(19) United States
(12) Patent Application Publication
(10) Pub. No.: US 2024/0421039 A1
(43) Pub. Date: Dec. 19, 2024

(54) SEMICONDUCTOR DEVICE

(71) Applicant: SAMSUNG ELECTRONICS CO., LTD., Suwon-si (KR)

(72) Inventors: Hyungeun CHOI, Suwon-si (KR); Kiseok LEE, Suwon-si (KR)

(73) Assignee: SAMSUNG ELECTRONICS CO., LTD., Suwon-si (KR)

(21) Appl. No.: 18/652,381

(22) Filed: May 1, 2024

(30) Foreign Application Priority Data
Jun. 19, 2023 (KR) 10-2023-0078263

(51) Int. Cl. H01L 23/48; H01L 23/00; H01L 25/065; H10B 80/00

(52) U.S. Cl. CPC H01L 23/481; H01L 24/08; H01L 25/0657; H10B 80/00; H01L 2224/08145

(57) ABSTRACT

A semiconductor device includes a lower chip structure including a memory structure and a lower wiring structure connected to the memory structure and an upper chip structure on the lower chip structure, where the upper chip structure includes an upper base, peripheral transistors below the upper base, an intermediate wiring structure below the upper base and connected to the peripheral transistors, an upper wiring structure on the upper base, a first through-via penetrating the upper base between the upper wiring structure and the intermediate wiring structure, the first through-via connecting the upper wiring structure and the intermediate wiring structure, and a second through-via extending respectively downward and penetrating the upper base between the upper wiring structure and the lower wiring structure, the second through-via connecting the upper wiring structure and the lower wiring structure.

### CROSS-REFERENCE TO RELATED APPLICATION(S)

This application is based on and claims priority to Korean Patent Application No. 10-2023-0078263, filed on Jun. 19, 2023, in the Korean Intellectual Property Office, the disclosure of which is incorporated herein by reference in its entirety.

### BACKGROUND

Example embodiments relate to a semiconductor device and a manufacturing method thereof.

Research is being conducted to reduce the size of elements constituting a semiconductor device and to improve performance thereof. For example, in a dynamic random access memory (DRAM), research is being conducted to reliably and stably form elements that have been reduced in size.

### SUMMARY

One or more example embodiments provide a semiconductor device having an increased degree of integration.

Additional aspects will be set forth in part in the description which follows and, in part, will be apparent from the description, or may be learned by practice of the presented embodiments.

According to an aspect of an example embodiment, a semiconductor device may include a lower chip structure including a memory structure and a lower wiring structure connected to the memory structure and an upper chip structure on the lower chip structure, where the upper chip structure may include an upper base, peripheral transistors below the upper base, an intermediate wiring structure below the upper base and connected to the peripheral transistors, an upper wiring structure on the upper base, a first through-via penetrating the upper base between the upper wiring structure and the intermediate wiring structure, the first through-via connecting the upper wiring structure and the intermediate wiring structure, and a second through-via extending respectively downward and penetrating the upper base between the upper wiring structure and the lower wiring structure, the second through-via connecting the upper wiring structure and the lower wiring structure.

According to an aspect of an example embodiment, a semiconductor device may include a lower chip structure including a first memory region, a second memory region, and an extension region between the first memory region and the second memory region, and an upper chip structure on the lower chip structure, where the lower chip structure may include a first bit line in the first memory region and extending into the extension region, a second bit line in the second memory region and extending into the extension region and routing lower wiring structures electrically connected to the first bit line and the second bit line, where the upper chip structure may include an upper base, peripheral transistors vertically overlapping the first memory region and below the upper base, routing intermediate wiring structures below the upper base and connected to the peripheral transistors, routing upper wiring structures on the upper base, first through-vias penetrating the upper base and connecting the routing upper wiring structures and the routing intermediate wiring structures, and second through-vias penetrating the upper base and connecting the routing upper wiring structures and the routing lower wiring structures, where the second through-vias are on the extension region and the first through-vias are on the first memory region.

According to an aspect of an example embodiment, a semiconductor device may include a lower chip structure including a memory structure and a lower wiring structure connected to the memory structure, and an upper chip structure on the lower chip structure, where the upper chip structure may include an upper base, peripheral transistors below the upper base, an intermediate wiring structure below the upper base and connected to the peripheral transistors, an upper wiring structure on the upper base, and through-vias penetrating at least the upper base, where the intermediate wiring structure may include intermediate vias at respective different levels and intermediate wirings at respective different levels, where the upper wiring structure may include at least one upper via and at least one upper wiring, and where a number of the intermediate wirings is greater than a number of the at least one upper wiring.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1A to 7 are diagrams illustrating a semiconductor device according to one or more example embodiments;

FIGS. 8A and 8B are diagrams illustrating a semiconductor device according to one or more example embodiments;

FIGS. 9A and 9B are diagrams illustrating a semiconductor device according to one or more example embodiments;

FIGS. 10A and 10B are diagrams illustrating a semiconductor device according to one or more example embodiments;

FIGS. 11A and 11B are diagrams illustrating a semiconductor device according to one or more example embodiments;

FIGS. 12 and 13 are diagrams illustrating an example of a memory structure of a semiconductor device according to one or more example embodiments;

FIG. 14 is a flowchart illustrating an example of a method of manufacturing a semiconductor device according to one or more example embodiments; and

FIGS. 15A to 17B are diagrams illustrating an example of a method of manufacturing a semiconductor device according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, the terms such as “upper,” “intermediate,” and “lower” may be replaced with other terms such as “first,” “second,” and “third” and may be used to describe elements of the specification. Terms such as “first,” “second,” and “third” may be used to describe different elements, but the elements are not limited by the terms, and a “first element” may be referred to as a “second element.”

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

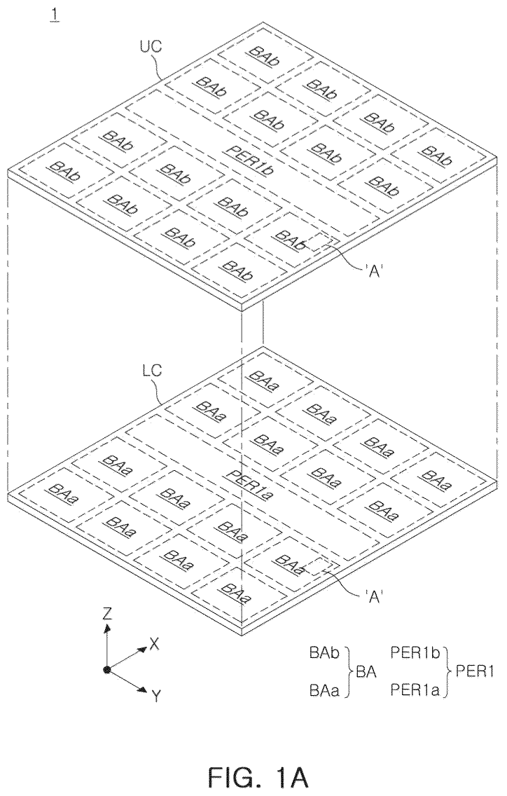

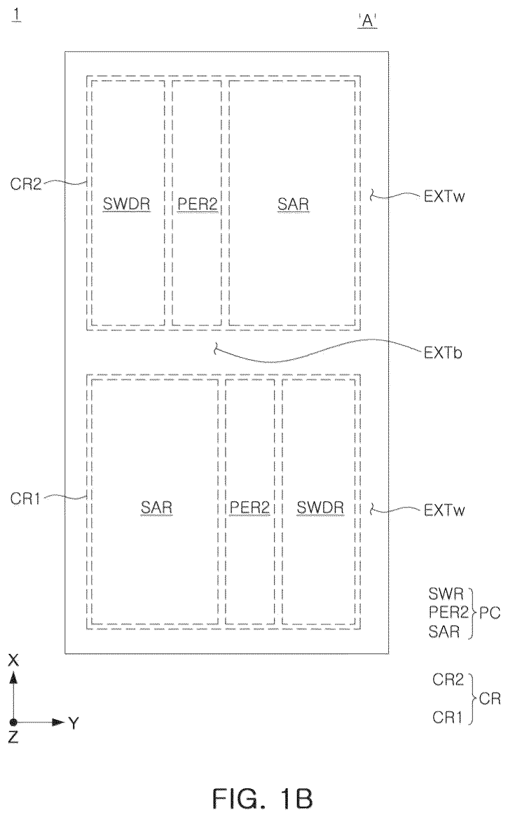

FIGS. 1A to 7 are diagrams illustrating a semiconductor device according to one or more example embodiments.

FIG. 1A is a perspective view illustrating a semiconductor device according to one or more example embodiments, and FIG. 1B is a plan view illustrating a portion of a bank BA of FIG. 1A according to one or more example embodiments.

Referring to FIGS. 1A and 1B, a semiconductor device 1 according to example embodiments may include a lower chip structure LC and an upper chip structure UC on the lower chip structure LC. The lower chip structure LC and the upper chip structure US may be sequentially stacked in a vertical direction (Z-direction).

The semiconductor device 1 may include a plurality of banks BA and a first peripheral region PER1. Each of the plurality of banks BA may include a lower region BAa in the lower chip structure LC and an upper region BAb in the upper chip structure UC.

The first peripheral region PER1 may include a first lower region PER1a in the lower chip structure LC and a first upper region PER1b in the upper chip structure UC. The first peripheral region PER1 may be a peripheral circuit region in which peripheral circuits for inputting data or commands, or power/ground, are disposed.

Each of the banks BA may include memory regions CR, extension regions EXTb and EXTw disposed adjacent to the memory regions CR, and peripheral circuit regions PC above (e.g., positioned vertically higher than) the memory regions CR. The peripheral circuit regions PC may vertically overlap the memory regions CR. The memory regions CR and the extension regions EXTb and EXTw may be disposed in the lower regions BAa of the banks BA of the lower chip structure LC, and the peripheral circuit regions PC may be disposed in the upper regions BAb of the banks BA of the upper chip structure UC.

Each of the memory regions CR may include cell switching devices including gate electrodes, bit lines electrically connected to the cell switching devices, and data storage structures electrically connected to the cell switching devices. The gate electrodes of the cell switching elements may be word lines.

The extension regions EXTb and EXTw may include an extension region EXTb disposed adjacent to the memory regions CR in a first direction (X-direction) and an extension region EXTw disposed adjacent to the memory regions CR in a second direction (Y-direction). The extension region EXTb disposed adjacent to the memory regions CR in the first direction (X-direction) may be a bit line extension region in which bit lines in the memory regions CR extend, and the extension region EXTw disposed adjacent to the memory regions CR in the second direction (Y-direction) may be a word line extension region in which word lines in the memory regions CR extend.

In example embodiments, the first direction (X-direction) and the second direction (Y-direction) may be perpendicular to each other. The first direction (X-direction) and the second direction (Y-direction) may be perpendicular to the vertical direction (Z-direction).

The memory regions CR may include a first memory region CR1 and a memory region CR2 disposed adjacent to the first memory region CR1 and spaced apart from the first memory region CR1 by the extension region EXTb.

Each of the peripheral circuit regions PC may include a sense amplifier region SAR, a sub-word line driver region SWDR, and a second peripheral region PER2 between the sense amplifier region SAR and the sub-word line driver region SWDR.

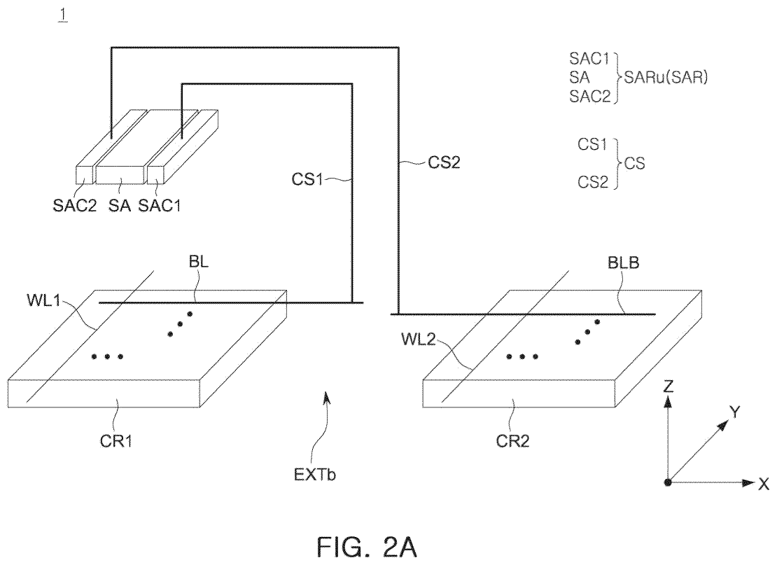

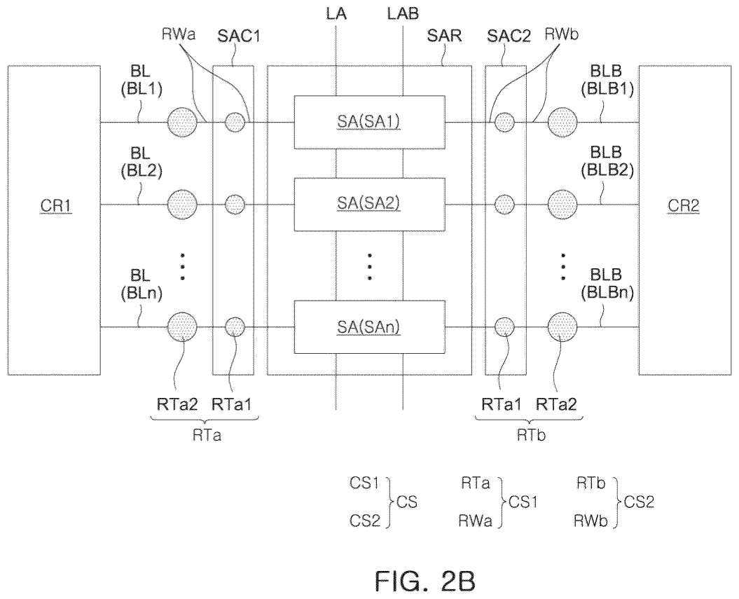

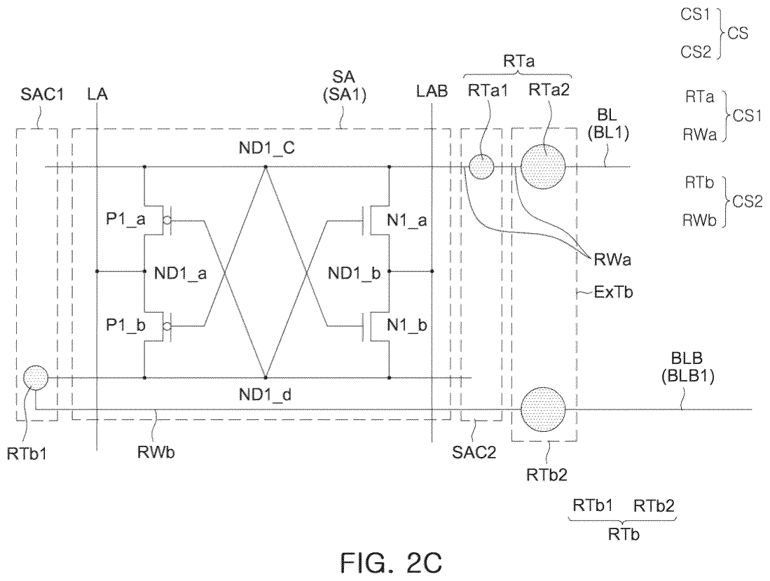

An electrical connection between the first and second memory regions CR1 and CR2 included in the lower chip structure LC and the sense amplifier region SAR included in the upper chip structure UC will be described with reference to FIGS. 2A, 2B, and 2C.

FIG. 2A is a perspective view illustrating an electrical connection relationship of a semiconductor device according to one or more example embodiments. FIG. 2B is a block diagram illustrating an electrical connection between the first and second memory regions CR1 and CR2 and the sense amplifier region SAR included in the upper chip structure UC, in a semiconductor device according to one or more example embodiments. FIG. 2C is a view including a circuit of the sense amplifier SA of FIGS. 2A and 2B, which is a view illustrating an electrical connection relationship between one sense amplifier SA1 of the sense amplifiers SA, one bit line BL1 electrically connected to the first sense amplifier SA1 among the plurality of bit lines BL, and one first complementary bit line BLB1 electrically connected to the first sense amplifier SA1 among the plurality of complementary bit lines BLB.

Referring to FIGS. 2A, 2B, and 2C together with FIGS. 1A and 1B, the first memory region CR1 may include a first memory structure including a bit line BL and a word line WL. The bit line BL may extend in the first direction (X-direction), and the word line WL1 may extend in the second direction (Y-direction), perpendicular to the first direction (X-direction).

The second memory region CR2 may include a second memory structure including a bit line BLB and a word line WL2. The bit line BLB may extend in the first direction (X-direction), and the word line WL2 may extend in the second direction (Y-direction).

In the semiconductor device 1, when the first memory region CR1 is a normal memory region and the second memory region CR2 is a reference memory region, the bit line BL of the first memory region CR1 may be a bit line for sensing data stored in a data storage structure in the first memory region CR1, and the bit line BL of the second memory region CR2 may be a bit line BL.

Hereinafter, the bit line BL of the first memory region CR will be referred to as a ‘bit line,’ and the bit line BLB of the second memory region CR2 will be referred to as a ‘complementary bit line.’

The sense amplifier region SAR may include a plurality of unit sense amplifier regions SARu. Each of the unit sense amplifier regions SARu may include a first connection region SAC1, a second connection region SAC2, and a sense amplifier SA between the first connection region SAC1 and the second connection region SAC2.

The semiconductor device 1 may include routing structures CS for electrically connecting the bit line BL of the first memory region CR1 and the complementary bit line BLB of the second memory region CR2 to the unit sense amplifier region SARu.

The routing structures CS may include a first routing structure CS1 electrically for connecting the bit line BL of the first memory region CR1 to the first connection region SAC1, and a second routing structure CS2 for electrically connecting the complementary bit line BLB of the second memory region CR2 to the second connection region SAC2.

A plurality of bit lines BL of the first memory region CR1 may be disposed, and the bit lines BL may be spaced apart from each other in the second direction (Y-direction). A plurality of complementary bit lines BLB of the second memory region CR2 may be disposed, and the complementary bit lines BLB may be spaced apart from each other in the second direction (Y-direction).

The bit lines BL of the first memory region CR1 may extend into the extension region EXTb and may be electrically connected to the first routing structures CS1. The complementary bit lines BLB of the second memory region CR2 may extend into the extension region EXTb and may be electrically connected to the second routing structures CS2.

The first memory region CR1 and the second memory region CR2 may be electrically connected to the sense amplifier region SAR. The bit lines BL of the first memory region CR1 may include n bit lines BL1, BL2, . . . , BLn, and the complementary bit lines BLB of the second memory region CR2 may include n complementary bit lines BL1, BL2, . . . , BLn. The sense amplifiers SA of the sense amplifier region SAR may include n sense amplifiers SA1, SA2, . . . , SAn. One sense amplifier SA1 of the sense amplifiers SA1, SA2, . . . , SAn may be electrically connected to one bit line BL1 of the bit lines BL1, BL2, . . . , BLn, and one complementary bit line BLB1 of the complementary bit lines BL1, BL2, . . . , BLn.

The bit lines BL and the sense amplifiers SA may be electrically connected to each other by the first routing structure CS1, and the complementary bit lines BLB and the sense amplifiers SA may be electrically connected by the second routing structure CS2.

Each of the routing structures CS may include routing through-vias RTa and RTb and routing wiring structures RWa and RWb. For example, the first routing structure CS1 may include first routing through-vias RTa and first routing wiring structure Rwa. The second routing structure CS2 may include second routing through-vias RTb and second routing wiring structures RWb.

The first sense amplifier SA1 may include a plurality of transistors P1_a, P1_b, N1_a, and N1_b.

The transistors P1_a, P1_b, N1_a, and N1_b may include a P1_a transistor and a P1_b transistor, which are P-channel transistors, and an N1_a transistor and an N1_b transistor, which are N-channel transistors. The P1_a transistor and the P1_b transistor may be referred to as a pair of P-channel transistors, and the N1_a transistor and the N1_b transistor may be referred to as a pair of N-channel transistor pairs.

In an example embodiment, the P-channel transistor may be a p-type metal-oxide-semiconductor (MOS) (PMOS) transistor, and the N-channel transistor may be an n-type MOS (NMOS) transistor.

A source of the P1_a transistor and a source of the P1_b transistor may be connected to a first control line LA through a first node ND1_a. A source of the N1_a transistor and a source of the N1_b transistor may be connected to a second control line LAB through a second node ND1_b.

The first node ND1_a and the second node ND1_b may be referred to as a first source node and a second source node, respectively.

A drain of the P1_a transistor and a drain of the N1_a transistor may be connected to the first bit line BL1 through a first drain node ND1_c. The first bit line BL1 may be electrically connected to the first drain node ND1_c by the first routing through-vias RTa and the first routing wiring structure Rwa.

A drain of the P1_b transistor and a drain of the N1_b transistor may be connected to the first complementary bit line BLB1 through a second drain node ND1_d. The first complementary bit line BLB1 may be electrically connected to the second drain node ND1_d by the second routing through-vias RTb and the second routing wiring structure RWb.

The first routing through-vias TRa may include a first sub-routing through-via TRa1 and a second sub-routing through-via TRa2, and the second routing through-vias TRb may include a third sub-routing through-via TRb1 and a fourth sub-routing through-via TRb2. The first sub-routing through-vias TRa1 may be disposed in the first connection region SAC1, and the third sub-routing through-vias TRb1 may be disposed in the second connection region SAC2. The second sub-routing through-vias TRa2 and the fourth sub-routing through-vias TRb2 may be disposed in the extension region EXTb.

The sense amplifier SA1 may sense and amplify a voltage change amount of the bit line BL1. When the sense amplifier SA1 performs sensing and amplification operations, an internal power voltage of the semiconductor device 1 may be applied to the first node ND1_a through the first control line LA, and the second node ND1_b may be connected to a ground terminal through the second control line LAB.

The sense amplifier SA1 of FIG. 2C includes a pair of P-channel transistors and a pair of N-channel transistors, and is implemented in a cross-coupled circuit configuration between transistors, but this is an exemplary embodiment, and the example embodiments are not limited thereto. For example, a circuit of the sense amplifier SA1 of FIG. 2C may be implemented in various circuit configurations.

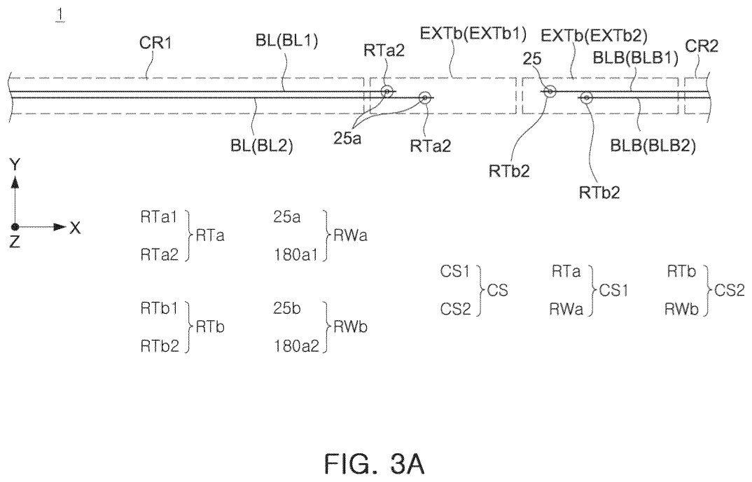

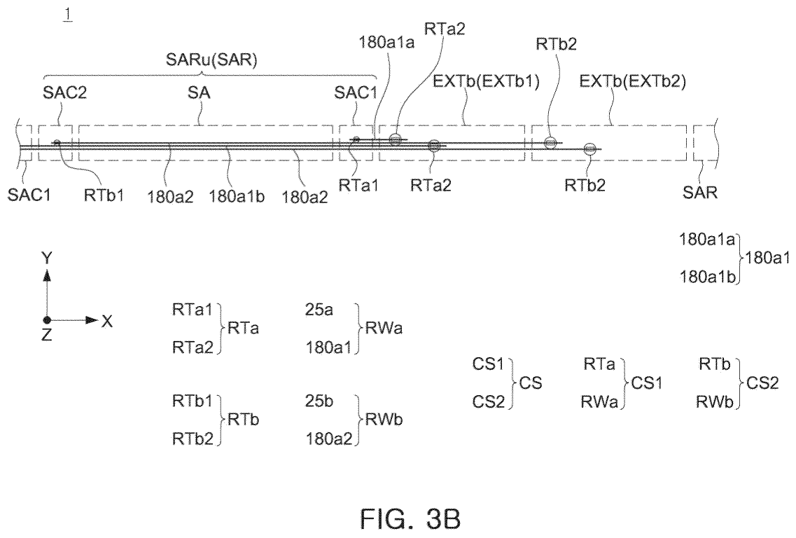

Next, an electrical connection between the first and second memory regions CR1 and CR2 and the sense amplifier region SAR will be described with reference to FIGS. 3A and 3B along with FIGS. 1A to 2C described above.

FIG. 3A is a top view illustrating an electrical connection between the first memory region CR1 and the second memory region CR2 according to one or more example embodiments. FIG. 3B is a top view illustrating an electrical connection between the first and second memory regions CR1 and CR2 and the sense amplifier region SAR according to one or more example embodiments.

Referring to FIGS. 3A and 3B along with FIGS. 1A to 2C, as described above, the first memory region CR1 may include bit lines BL, and the second memory region CR2 may include complementary bit lines BLB.

The extension region EXTb between the first memory region CR1 and the second memory region CR2 may include a first side extension region EXTb1 disposed adjacent to the first memory region CR1 and a second side extension region EXTb2 disposed adjacent to the second memory region CR2.

The bit lines BL may include a first bit line BL1 and a second bit line BL2 disposed adjacent to each other. The complementary bit lines BLB may include a first complementary bit line BLB1 and a second complementary bit line BLB2 disposed adjacent to each other.

The bit lines BL may extend from the first memory region CR1 to the first side extension region EXTb1, and the complementary bit lines BLB may extend from the second memory region CR2 to the second side extension region EXTb2.

The first routing wiring structure RWa may include a first sub-routing lower wiring structure 25a and a first sub-routing upper wiring structure 180a1, which are electrically connected to the second sub-routing through-via RTa2.

The second routing wiring structure RWb may include a second sub-routing lower wiring structure 25b and a second sub-routing upper wiring structure 180a2, which are electrically connected to the fourth sub-routing through-via RTb2.

The first bit line BL1 and the first complementary bit line BLB1 electrically connected to a unit sense amplifier SARu illustrated in FIG. 3B will be mainly described.

The first sub-routing upper wiring structure 180a1 may extend from the first side extension region EXTb1 to the first connection region SAC1. The first sub-routing upper wiring structure 180a1 may be electrically connected to the second sub-routing through-via RTa2 in the first side extension region EXTb1, and may be electrically connected to the first sub-routing through-via TRa1 in the first connection region SAC1. Accordingly, the first sub-routing upper wiring structure 180a1 may electrically connect the second sub-routing through-via RTa2 and the first sub-routing through-via TRa1.

The second sub-routing upper wiring structure 180a2 may extend from the second side extension region EXTb2 to the second connection region SAC2. The second sub-routing upper wiring structure 180a2 may be electrically connected to the fourth sub-routing through-via RTb2 in the second side extension region EXTb2, and may be electrically connected to the third sub-routing through-via TRb1 in the second connection region SAC2. Accordingly, the second sub-routing upper wiring structure 180a2 may electrically connect the fourth sub-routing through-via RTb2 and the second sub-routing through-via TRb1.

The first sub-routing upper wiring structure 180a1 may include a first sub-routing upper wiring structure 180a1a and a first sub-routing upper wiring structure 180a1b. The first sub-routing upper wiring structure 180a1a may not vertically overlap the sense amplifier SA, and the first sub-routing upper wiring structure 180a 1b may vertically overlap the sense amplifier SA. The second sub-routing upper wiring structure 180a2 may vertically overlap or at least be positioned within the width of the sense amplifier SA.

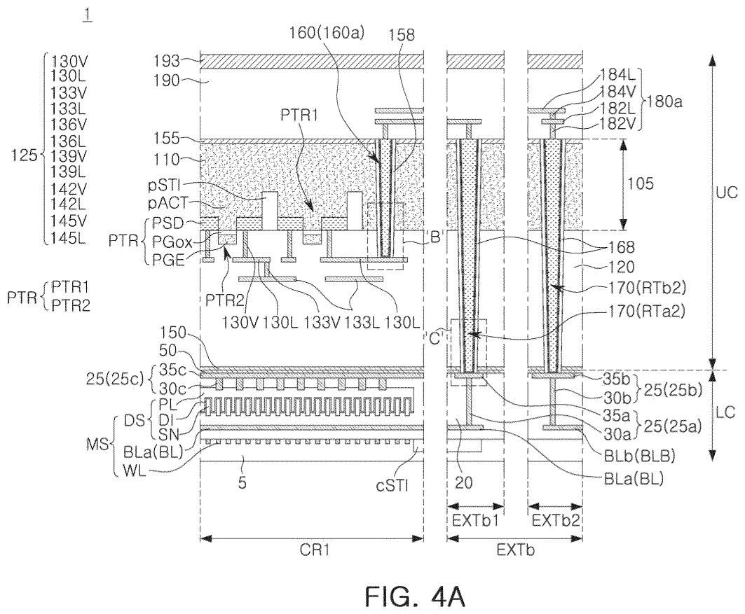

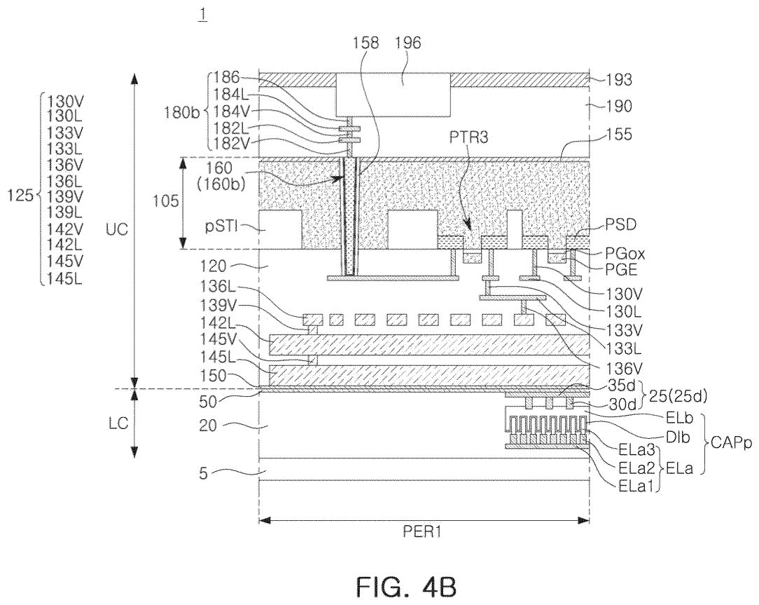

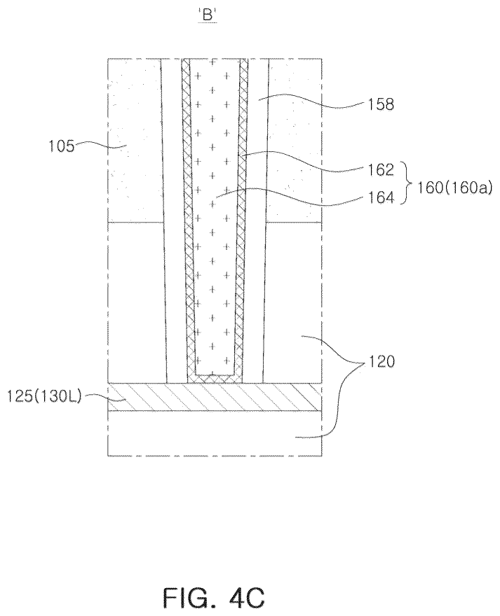

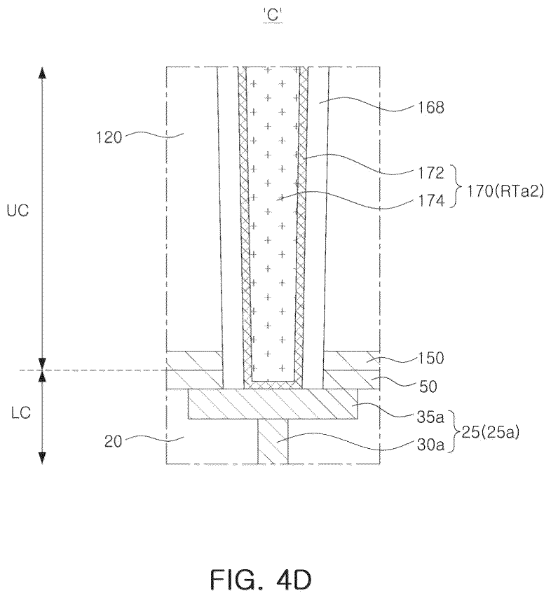

Next, a cross-sectional structure of the semiconductor device 1 described with reference to FIGS. 1A to 3B will be described with reference to FIGS. 4A to 4D.

FIG. 4A is a cross-sectional view illustrating a portion of a bank BA of a semiconductor device according to one or more example embodiments. FIG. 4B is a cross-sectional view illustrating a portion of the first peripheral circuit PER1 of a semiconductor device according to one or more example embodiments. FIG. 4C is a partially enlarged view of a region indicated by ‘B’ in FIG. 4A according to one or more example embodiments. FIG. 4D is a partially enlarged view illustrating a region indicated by “C” of FIG. 4A according to one or more example embodiments.

In FIG. 4A, a region indicated by ‘CR1’ may represent the first memory region of the lower chip structure LC described above, a region indicated by ‘EXTb’ may represent the extension region described above, a region indicated by ‘EXTb1’ may represent the first extension region described above, and a region indicated by ‘EXTb2’ may represent the second extension region described above.

Referring to FIGS. 4A to 4D together with FIGS. 1A to 3B, as described above, the semiconductor device 1 may include the lower chip structure LC and the upper chip structure UC sequentially stacked.

As described above, the lower chip structure LC may have the first peripheral circuit region PER1, the first memory region CR1, the second memory region CR2, and an extension region EXTb between the first and second memory regions CR1 and CR2.

The lower chip structure LC may include a lower base 5, memory structures MS and a power capacitor CAPp on the lower base 5, routing lower wiring structures 25 electrically connected to the memory structures MS and the power capacitor CAPp on the lower base 5, a lower insulating structure 20 for covering or at least partially covering the memory structures MS and the routing lower wiring structures 25 on the lower base 5, and a lower bonding insulating layer 50 on the lower insulating structure 20.

Each of the memory structures MS may include word lines ML, bit lines BLa and BLb, and data storage structures DS. Each of the data storage structures DS may include first electrodes SN, a second electrode PL covering or at least partially covering the first electrodes SN, and a dielectric layer DI between the first electrodes SN and the second electrode PL.

The lower base 5 may include a lower semiconductor substrate and a device isolation region cSTI on the lower semiconductor substrate. The word lines WL may be embedded in the lower base 5.

The data storage structures DS may be memory cell capacitors capable of storing data in a memory such as a dynamic random access memory (DRAM).

The first peripheral circuit region PER1 may include the power capacitor CAPp. The power capacitor CAPp may include a lower electrode ELa, an upper electrode ELb, and a dielectric layer DIb between the lower and upper electrodes Ela and ELb. The lower electrode ELa may include a first lower electrode ELa1, second lower electrodes ELa2 on the first lower electrode ELa1, and third lower electrodes ELa3 on the second lower electrodes ELa2. The third lower electrodes ELa3 may be disposed on substantially the same level as that of the first electrodes SN.

The first memory region CR1 may include a first memory structure of the memory structures MS, and the second memory region CR2 may include a second memory structure of the memory structures MS.

Among the bit lines BLa and BLb, the first memory structure of the first memory region CR1 may include a bit line indicated by BLa, and the bit line BLa may be a bit line BL electrically connected to the sense amplifier SA described above.

Among the bit lines BLa and BLb, the second memory structure of the second memory region CR2 may include a bit line indicated by BLb, and the bit line BLb may be a complementary bit line BLB electrically connected to the sense amplifier SA described above.

Hereinafter, the BLa bit line will be referred to and described as a bit line BL electrically connected to the sense amplifier SA, and the BLb bit line will be referred to and described as the complementary bit line BLB electrically connected to the sense amplifier SA described above.

The routing lower wiring structures 25 may include a first sub-routing lower wiring structure 25a electrically connected to the bit line BL, a second sub-routing lower wiring structure 25b electrically connected to the complementary bit line BLB, a third sub-routing lower wiring structure 25c electrically connected to the second electrode PL, and a fourth sub-routing lower wiring structure 25d electrically connected to the upper electrode ELb.

Each of the routing lower wiring structures 25 may include a vertical portion and a horizontal portion. For example, the first sub-routing lower wiring structure 25a may include a vertical portion 30a contacting and electrically connected to the bit line BL and a horizontal portion 35a connected to the vertical portion 30a on the vertical portion 30a, the second sub-routing lower wiring structure 25b may include a vertical portion 30b contacting and electrically connected to the complementary bit line BLB and a horizontal portion 35b connected to the vertical portion 30b on the vertical portion 30b, the third sub-routing lower wiring structure 25c may include a vertical portion 30c contacting and electrically connected to the second electrode PL and a horizontal portion 35c connected to the vertical portion 30c on the vertical portion 30c, and a fourth sub-routing lower wiring structure 25d may include a vertical portion 30d contacting and electrically connected to the upper electrode ELb and a horizontal portion 35d connected to the vertical portion 30d on the vertical portion 30d.

In each of the routing lower wiring structures 25, the vertical portions 30a, 30b, 30c and 30d may be contact plugs, and the horizontal portions 35a, 35b, 35c and 35d may be pads or interconnection lines including pads.

Upper surfaces of the horizontal portions 35a, 35b, 35c and 35d may contact a lower surface of the lower bonding insulating layer 50.

The upper chip structure UC may include an upper bonding insulating layer 150, an upper base 105, peripheral transistors PTR, routing intermediate wiring structures 125, intermediate insulating structures 120, routing upper wiring structures 180a and 180b (also referred to herein as an input/output connection structure), an upper insulating structure 190, the capping insulating layer 193, an input/output connection structure 180b, an input/output pad 196, first through-vias 160, second through-vias 170, and first insulating spacers 158 and second insulating spacers 168.

The upper bonding insulating layer 150 may contact and be bonded to the lower bonding insulating layer 50. The lower bonding insulating layer 50 and the upper bonding insulating layer 150 may include the same material. Each of the lower and upper bonding insulating layers 50 and 150 may include at least one of silicon oxide, SiCN, and SiCON.

The upper base 105 may be disposed on the upper bonding insulating layer 150. The upper base 105 may include an upper semiconductor substrate 110, upper active regions pACT below the upper semiconductor substrate 110, and an upper device isolation region pSTI defining the upper active regions pACT below the upper semiconductor substrate 110.

Each of the peripheral transistors PTR may include upper gates PGox and PGE below the upper base 105, and upper sources/drains PSD in the upper active region pACT on both sides of the upper gates PGox and PGE. The upper gates PGox and PGE may include an upper gate electrode PGE, and an upper gate dielectric layer PGox between the upper gate electrode PGE and the upper active region pACT.

The peripheral transistors PTR may include transistors PTR1 and PTR2 above (e.g., positioned vertically higher than) the memory structures MS of the first and second memory regions CR1 and CR2, and transistors PTR3 above (e.g., positioned vertically higher than) the first peripheral circuit region PER1. For example, the peripheral transistors PTR may include first and second transistors PTR1 and PTR2 that may form the plurality of transistors P1_a, P1_b, N1_a, and N1_b (see FIG. 2C) of the sense amplifiers SA simultaneously with above (e.g., positioned vertically higher than) the memory structure MS of the first memory region CR1. The transistors PTR1 and PTR2 may vertically overlap the memory structures MS of the first and second memory regions CR1 and CR2. The transistors PTR3 may vertically overlap the first peripheral circuit region PER1. The first and second transistors PTR1 and PTR2 may vertically overlap the memory structure MS of the first memory region CR1.

The routing intermediate wiring structures 125 may electrically connect the peripheral transistors PTR to form a peripheral circuit. The routing intermediate wiring structures 125 may include vertical portions 130V, 133V, 136V, 139V, 142V and 145V disposed on different levels and horizontal portions 130L, 133L, 136L, 139L, 142L and 145L disposed on different levels.

In the routing intermediate wiring structures 125, the horizontal portions 130L, 133L, 136L, 139L, 142L and 145L may be two or more layers disposed on different levels.

In example embodiments, the “vertical portion” may be a vertically extending plug or via, and the “horizontal portion” may be a horizontally extending pad or a wiring including a pad. Therefore, the “vertical portion” may be referred to as a plug or a via, and the “horizontal portion” may be referred to as an interconnection line.

In example embodiments, terms such as a ‘lower surface’, an ‘upper surface’, ‘uppermost,’ and ‘lowermost’ may be described based on the drawings. For example, an uppermost horizontal portion of the horizontal portions 1u30L, 133L, 136L, 139L, 142L and 145L may be a horizontal portion indicated by 130L closest to the upper base 105 based on FIG. 4A.

The intermediate insulating structure 120 may be disposed between the upper base 105 and the upper bonding insulating layer 150. The peripheral gates PGox and PGE and the routing intermediate wiring structures 125 may be embedded in the intermediate insulating structure 120.

A lower surface of a lowermost horizontal portion 145L of the horizontal portion 130L, 133L, 136L, 139L, 142L and 145L of the routing intermediate wiring structures 125 may contact an upper surface of the upper bonding insulating layer 150.

The routing upper wiring structures 180a may include at least one vertical portion 182V or 184V and at least one horizontal portion 182L or 184L. In the routing upper wiring structures 180a, the vertical portions 182V and 184V may be disposed below the horizontal portions 182L and 184L.

The number of horizontal portions 130L, 133L, 136L, 139L, 142L and 145L disposed on different levels among the routing intermediate wiring structures 125 may be greater than the number of at least one horizontal portion 182L or 184L disposed on different levels among the routing upper wiring structures 180a.

For example, in the routing upper wiring structures 180a, the horizontal portions 182L and 184L may be one connection line layer.

In another example, in the routing upper wiring structures 180a, the horizontal portions 182L and 184L may be two or more wiring layers disposed on different levels.

The input/output connection structure 180b may include vertical portions 182V, 184V and 186) and horizontal portions 182L and 184L.

The upper insulating structure 190 may cover or at least partially cover the routing upper wiring structures 180a and the input/output connection structure 180b on the upper base 105.

The capping insulating layer 193 may be disposed on the upper insulating structure 190 and may serve to protect the semiconductor device 1.

The input/output pad 196 may be electrically connected to the input/output connection structure 180b on the input/output connection structure 180b.

The first through-vias 160 may penetrate through the upper base 105. The first through-vias 160 may electrically connect the routing upper wiring structures 180 and the routing intermediate wiring structures 125.

The first through-vias 160 may contact and be simultaneously electrically connected to the uppermost horizontal portion 130L among the horizontal portions 130L, 133L, 136L, 139L, 142L and 145L of the routing intermediate wiring structures 125.

Each of the first through-vias 160 may include a conductive pillar 164 and a barrier layer 162 covering or at least partially covering a side surface and a lower surface of the conductive pillar 164.

The first through-vias 160 may include through-vias 160a above (e.g., positioned vertically higher than) the first memory region CR1 and electrically connected to the first and second transistors PTR1 and PTR2 constituting the sense amplifiers SA (see FIGS. 2A to 2C) through the routing intermediate wiring structures 125, and an input/output through-via 160b electrically connected to the input/output connection structure 180b on the first peripheral circuit region PER1. The through-vias 160a may vertically overlap the first memory region CR1.

Each of the second through-vias 170 may include a conductive pillar 174 and a barrier layer 172 covering or at least partially covering a side surface and a lower surface of the conductive pillar 174.

The second through-vias 170 may be above (e.g., positioned vertically higher than) the extension region EXTb. The second through-vias 170 may vertically overlap the extension region EXTb. The second through-vias 170 may penetrate through the upper base 105 to extend downward, and penetrate through the intermediate insulating structure 120, the upper bonding insulating layer 150, and the lower bonding insulating layer 50. The second through-vias 170 may electrically connect the routing upper wiring structures 180 and the routing lower wiring structures 25. The second through-vias 170 may include a second sub-routing through-vias TRa2 electrically connected to the bit line BL through the first sub-routing lower wiring structure 25a, and a fourth sub-routing through-vias TRb2 electrically connected to the complementary bit line BLB through the second sub-routing lower wiring structure 25b.

The first through-vias 160 may have side surfaces inclined such that a width thereof decreases in a direction oriented from top to bottom. The second through-vias 170 may have side surfaces inclined such that a width thereof decreases in a direction oriented from top to bottom.

The first insulating spacers 158 may cover or at least partially cover side surfaces of the first through-vias 160. The second insulating spacers 168 may cover or at least partially cover side surfaces of the second through-vias 170.

A maximum width of each of the second through-vias 170 may be greater than a maximum width of each of the first through-vias 160. A height between an upper surface and a lower surface of each of the second through-vias 170 may be greater than a height between an upper surface and a lower surface of each of the first through-vias 160.

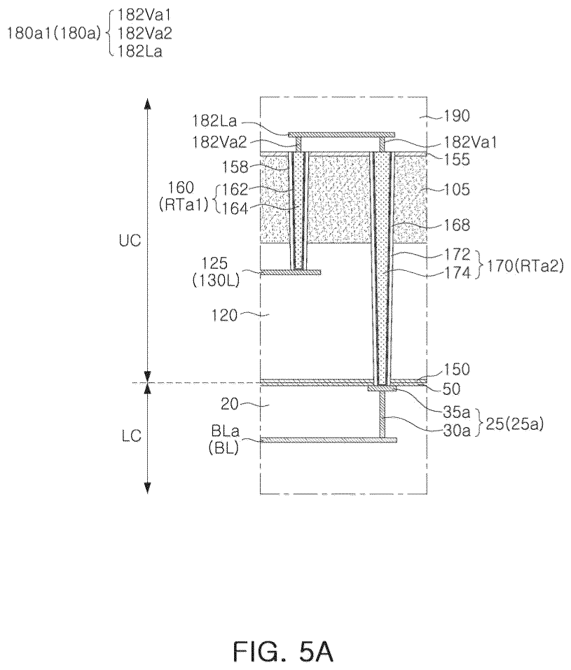

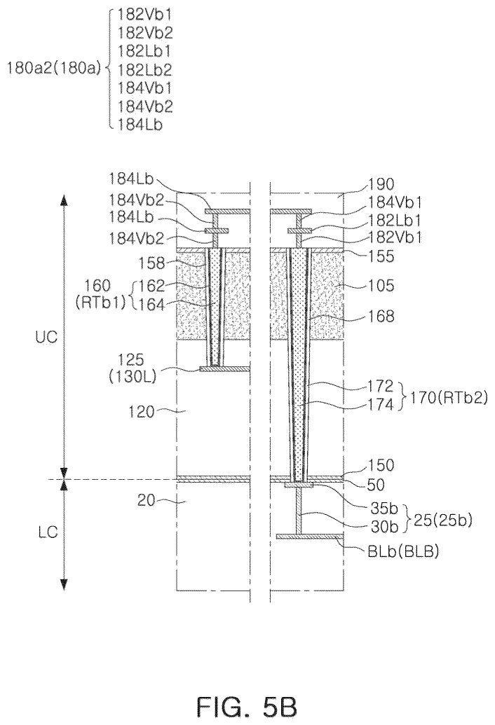

Hereinafter, exemplary examples of routing structures will be described with reference to FIGS. 5A, 5B, 6A, 6B, and 7.

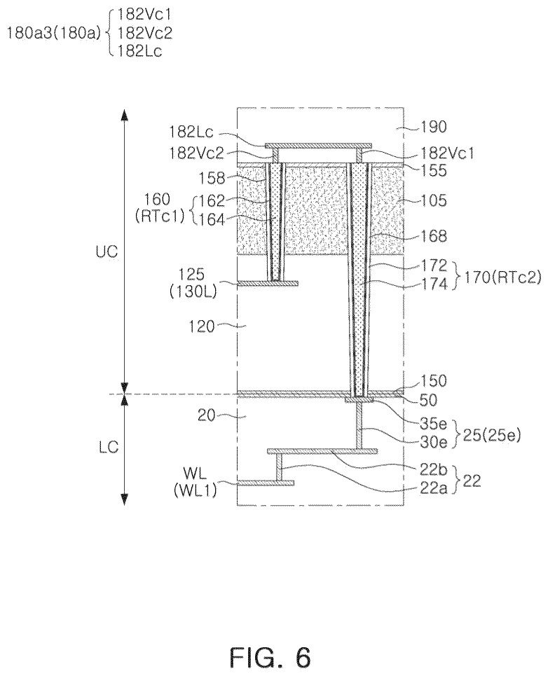

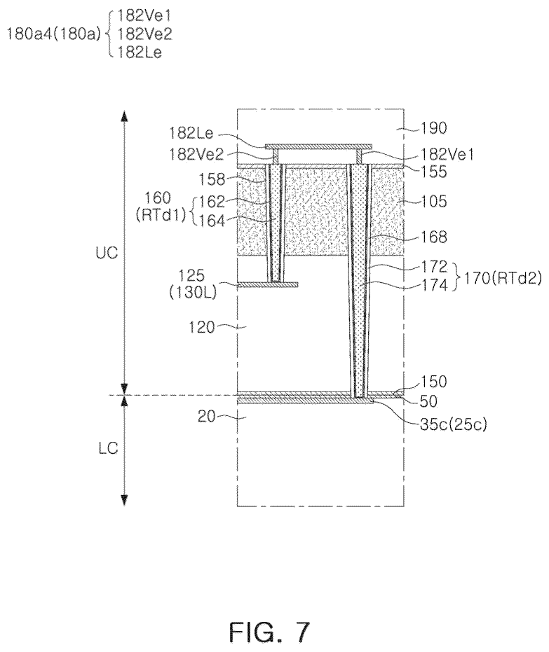

FIG. 5A is a partially enlarged cross-sectional view illustrating a routing structure for electrically connecting the bit line BL and the sense amplifier SA (see FIGS. 2A, 2B, 2C and 3B) according to one or more example embodiments. FIG. 5B is a partially enlarged cross-sectional view illustrating a routing structure for electrically connecting the complementary bit line BLB and the sense amplifier SA (see FIGS. 2A, 2B, 2C and 3B) according to one or more example embodiments. FIG. 6A is a partially enlarged cross-sectional view illustrating a routing structure connected to a first word line WL1 among the word lines WL of the memory structure MS according to one or more example embodiments. FIG. 6B is a partially enlarged cross-sectional view illustrating a routing structure connected to a second word line among the word lines WL of the memory structure MS according to one or more example embodiments. FIG. 7 is a partially enlarged cross-sectional view illustrating a routing structure electrically connected to the second electrode PL of the memory structure MS according to one or more example embodiments.

Referring to FIG. 5A together with FIGS. 1A to 4D, the bit line BL of the memory structure MS in the first memory area CR1 may be electrically connected to a first sub-routing lower wiring structure 25a among the lower wiring structures 25, a second sub-routing through-via RTa2 among the second through-vias 170, a first sub-routing upper wiring structure 180a1 among the routing upper wiring structures 180a, a first sub-routing through-via RTa1 among the first through-vias 160, and the first transistor PTR1 (see FIG. 4A) constituting the sense amplifier SA (see FIGS. 2A, 2B, 2C and 3B), through the routing intermediate wiring structure 125.

The first sub-routing upper wiring structure 180a1 may electrically connect the first sub-routing through-via RTa1 and the second sub-routing through-via RTa2.

The first sub-routing upper wiring structure 180a1 may include a vertical portion 182Va1 connected to the second sub-routing through-via RTa2, a vertical portion 182Va2 connected to the first sub-routing through-via RTa1, and a horizontal portion 182La2 for electrically connecting the vertical portions 182Va1 and 182Va2.

The horizontal portion 182La of the first sub-routing upper wiring structure 180a1 may be a single wiring layer disposed on any height level, but the example embodiment is not limited thereto. For example, the horizontal portion 182La of the first sub-routing upper wiring structure 180a1 may be include two or more wiring layers disposed on different levels.

Referring to FIG. 5B, together with FIGS. 1A to 5A, the complementary bit line BLB of the memory structure MS in the second memory area CR2 may be electrically connected to the second sub-routing lower wiring structure 25b among the lower wiring structures 25, a fourth sub-routing through-via RTb2 among the second through-vias 170, a second sub-routing upper wiring structure 180a2 among the routing upper wiring structures 180a, a third sub-routing through-via RTb1 among the first through-vias 160, and the second transistor PTR2 (see FIG. 4A) constituting the sense amplifier SA (see FIGS. 2A, 2B, 2C and 3B), through the routing immediate wiring structure 125.

The second sub-routing upper wiring structure 180a2 may electrically connect the third sub-routing through-via TRb1 and the fourth sub-routing through-via RTb2.

The second sub-routing upper wiring structure 180a2 may include vertical portions 182Vb1, 184Vb1 and 182Vb2 and horizontal portions 182Lb1, 182Lb2 and 184L.

The horizontal portions 182Lb1, 182Lb2 and 184L of the second sub-routing upper wiring structure 180a2 may be two or more wiring layers disposed on different levels, but the example embodiment is not limited thereto. For example, the horizontal portions 182Lb1, 182Lb2 and 184L of the second sub-routing upper wiring structure 180a2 may include a single wiring layer disposed on any height level.

Referring to FIG. 6, together with FIGS. 1A to 5B, one word line WL1 of the word lines WL may be electrically connected to a fifth sub-routing lower wiring structure 25e of the lower wiring structures 25, a sixth sub-routing through-via RTc2 among the second through-vias 170, a third sub-routing upper wiring structure 180a3 among the routing upper wiring structures 180a, a fifth sub-routing through-via RTc1 among the first through-vias 160, and a peripheral circuit including any one of the transistors PTR, through the routing intermediate wiring structure 125.

The third sub-routing upper wiring structure 180a3 may electrically connect the fifth sub-routing through-via RTc1 and the sixth sub-routing through-via RTc2.

The third sub-routing upper wiring structure 180a3 may include vertical portions 182Vc1 and 182Vc2 and a horizontal portion 182Lc.

The horizontal portion 182Lc of the third sub-routing upper wiring structure 180a3 may be a single wiring layer disposed on any height level, but the example embodiment is not limited thereto. For example, the horizontal portion 182Lc of the third sub-routing upper wiring structure 181a3 may include two or more wiring layers disposed on different levels.

Referring to FIG. 7, together with FIGS. 1A to 6, the second electrode 35 of the data storage structure DS may be connected to a third sub-routing lower wiring structure 25c among the lower wiring structures 25, an eighth sub-routing through-via RTd2 among the second through-vias 170, a fourth sub-routing upper wiring structure 180a4 among the routing upper wiring structures 180a, a seventh sub-routing through-via RTd1 among the first through-vias 160, and a peripheral circuit including any one of the transistors PTR through the routing intermediate wiring structure 125.

The fourth sub-routing upper wiring structure 180a4 may electrically connect the seventh sub-routing through-via RTd1 and the eighth sub-routing through-via RTd2.

The fourth sub-routing upper wiring structure 180a4 may include vertical portions 182Ve1 and 182Ve2 and a horizontal portion 182Le.

The horizontal portion 182Le of the fourth sub-routing upper wiring structure 180a4 may be a single wiring layer disposed on any one height level, but the example embodiment is not limited thereto. For example, the horizontal portion 182Le of the fourth sub-routing upper wiring structure 181a4 may include two or more wiring layers disposed on different levels.

Next, various modified examples of the elements of the example embodiment described above will be described. Various modified examples of the elements of the above-described example embodiment will be described based on a modified element or a replaced element. The elements described above may be directly cited without further explanation, or description thereof may be omitted. Furthermore, the modified or replaceable elements described below are described in reference to the following drawings, but the modified or replaceable elements may be combined with each other or combined with the aforementioned elements to form a semiconductor device according to an example embodiment of the present disclosure.

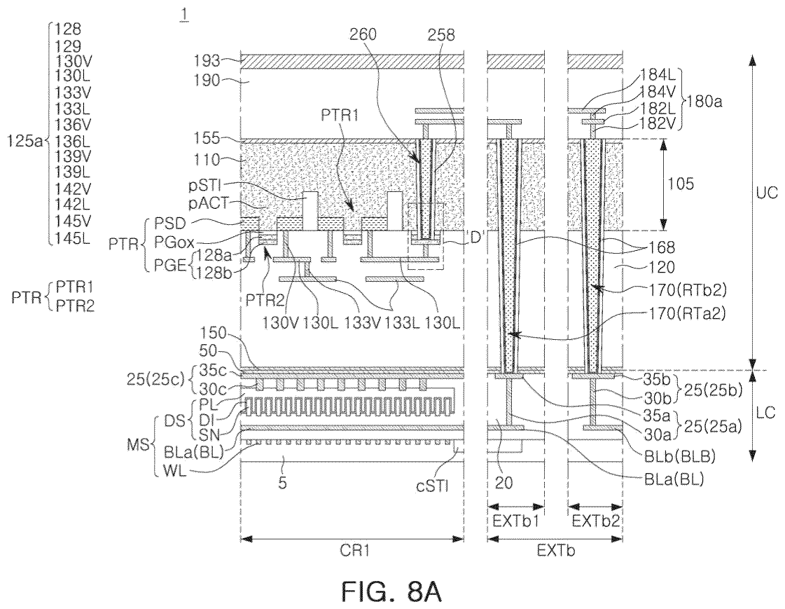

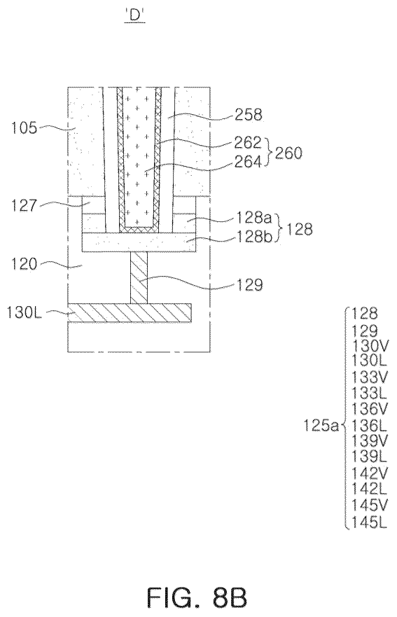

FIGS. 8A and 8B are diagrams illustrating a semiconductor device according to one or more example embodiments. FIG. 8A is a cross-sectional view illustrating elements modified in the cross-sectional structure of FIG. 4A according to one or more example embodiments. FIG. 8B is a partially enlarged view of a region indicated by “D” of FIG. 8A according to one or more example embodiments.

Referring to FIGS. 8A and 8B, the first through-via 160 described above may penetrate through the upper base 105 and may be replaced with a first through-via 260 having a lower surface disposed on the same level as a portion of the upper gate electrode PGE. The routing intermediate wiring structures 125a may be replaced with routing intermediate wiring structures 125a which further include an uppermost horizontal portion 128 disposed on the same level as the upper gate electrode PGE and a vertical portion 129 between the uppermost horizontal portion 128 and a next uppermost horizontal portion 130L below the uppermost horizontal portion 128.

The uppermost horizontal portion 128 may include at least two conductive layers 128a and 128b. The first through-via 260 may penetrate through at least one of the at least two conductive layers 128a and 128b and may be electrically connected to the uppermost horizontal portion 128.

The semiconductor device 1 may further include a buffer dielectric layer 127 between the uppermost horizontal portion 128 and the upper base 105.

The first through-via 260 may include a conductive pillar 264 and a barrier layer 262 covering or at least partially covering a side surface and a lower surface of the conductive pillar 264.

The first through-via 260 may have a lower surface contacting the uppermost horizontal portion 128. The lower surface of the first through-via 260 may be disposed on a lower level than a lower surface of the upper base 105 and may be disposed on a higher level than a lower surface of the uppermost horizontal portion 128.

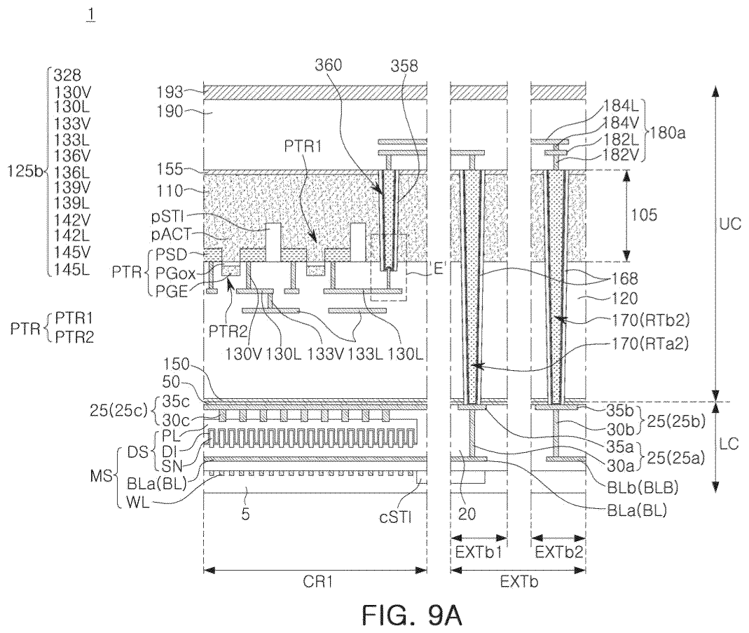

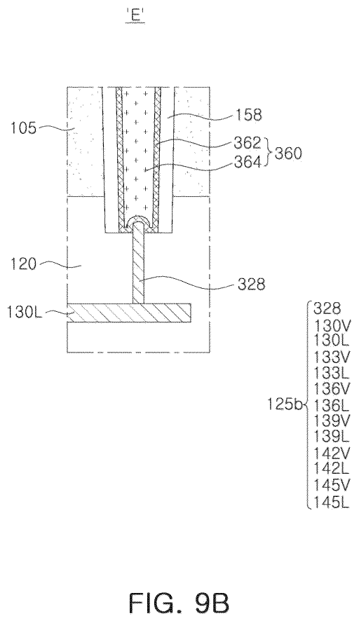

FIGS. 9A and 9B are diagrams illustrating a semiconductor device according to one or more example embodiments. FIG. 9A is a cross-sectional view illustrating elements modified in the cross-sectional structure of FIG. 4A according to one or more example embodiments. FIG. 9B is a partially enlarged view of a region indicated by “E” of FIG. 9A according to one or more example embodiments.

Referring to FIGS. 9A and 9B, the routing intermediate wiring structures 125 may be replaced with routing intermediate wiring structures 125b further including an uppermost vertical portion 328 on the uppermost horizontal portion 130L described above.

The first through-via 160 described above may penetrate through the upper base 105 to extend downward and may be replaced with a first through-via 360 contacting the uppermost vertical portion 328. The first through-via 360 may include a conductive pillar 364 and a barrier layer 362 covering or at least partially covering a side surface and a lower surface of the conductive pillar 364.

The uppermost vertical portion 328 may be referred to as a ‘contact plug’ or a ‘conductive via.’

The uppermost vertical portion 328 may extend into the first through-via 36. Accordingly, the lower end of the first through-via 36 may be disposed at a higher level than the upper end of the uppermost vertical portion 328.

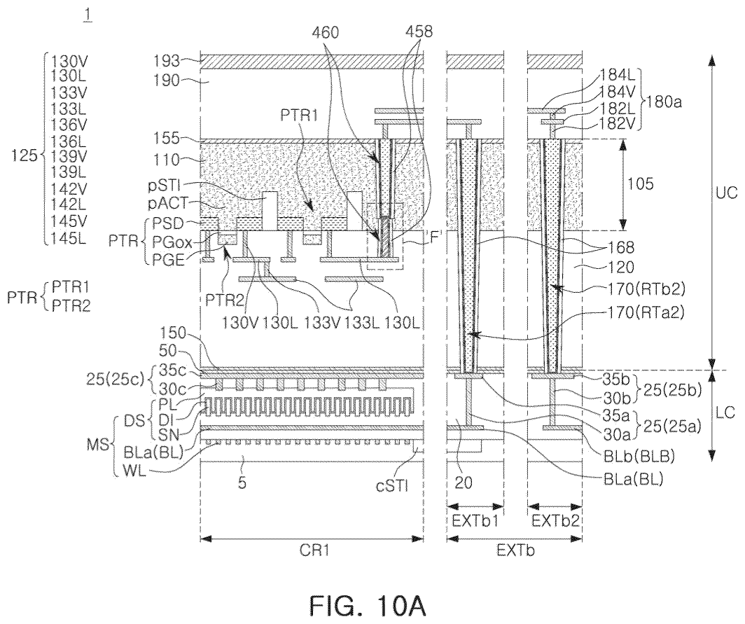

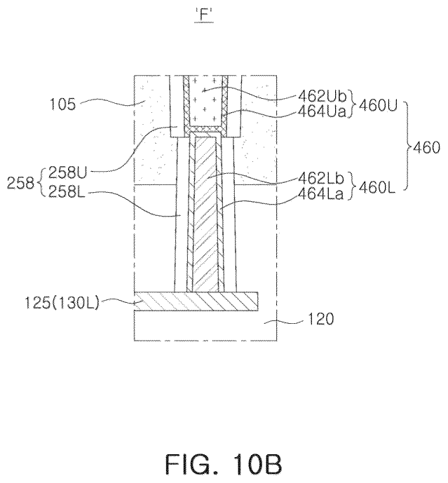

FIGS. 10A and 10B are diagrams illustrating a semiconductor device according to one or more example embodiments. FIG. 10A is a cross-sectional view illustrating elements modified in the cross-sectional structure of FIG. 4A according to one or more example embodiments. FIG. 10B is a partially enlarged view of a region indicated by “F” of FIG. 10A according to one or more example embodiments.

Referring to FIGS. 10A and 10B, the first through-via 160 described above may be replaced with a first through-via 460 including an upper through-via 460U and a lower through-via 460L.

The upper through-via 460U may extend downward from an upper surface of the upper base 105 and have a lower surface inside the upper base 105. The lower through-via 460L may extend upwardly from a lower portion of the upper base 105 to contact the upper through-via 460U inside the upper base 105. The lower through-via 460L may be electrically connected to the routing intermediate wiring structure 125.

A contact region in which the upper through-via 460U and the lower through-via 460L are contacting each other may be disposed on a height level between the upper surface of the upper base 105 and the lower surface of the upper base 105.

The upper through-via 460U include a conductive pillar 462Ub and a barrier layer 464Ua covering or at least partially covering a side surface and a lower surface of the conductive pillar 462Ub. The lower through-via 460L may include a conductive pillar 462Lb and a barrier layer 464La covering or at least partially covering a side surface and an upper surface of the conductive pillar 462Lb.

The first insulating spacer 158 described above may be replaced with a first insulating spacer 258 including an upper insulating spacer 258U covering or at least partially covering a side surface of the upper through-via 460U and a lower insulating spacer 258L covering or at least partially covering a side surface of the lower through-via 460L. The first through-via 460 may be spaced apart from the upper base 105 by the first insulating spacer 258.

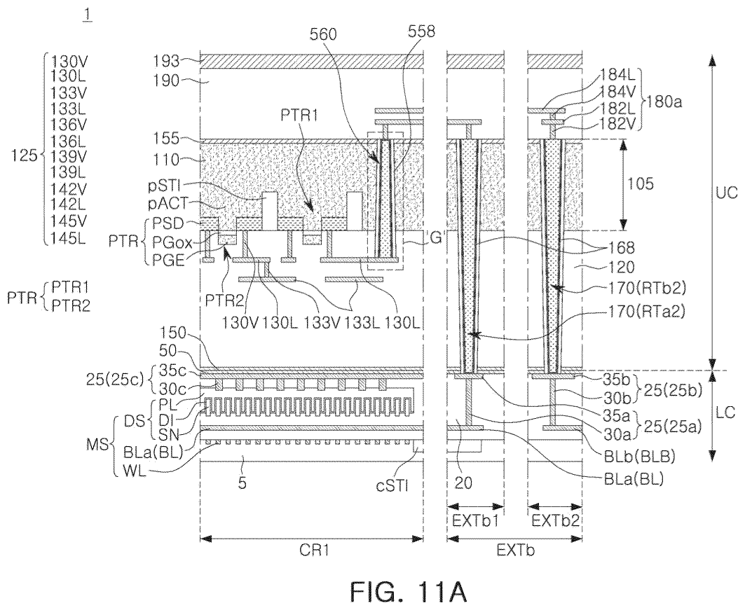

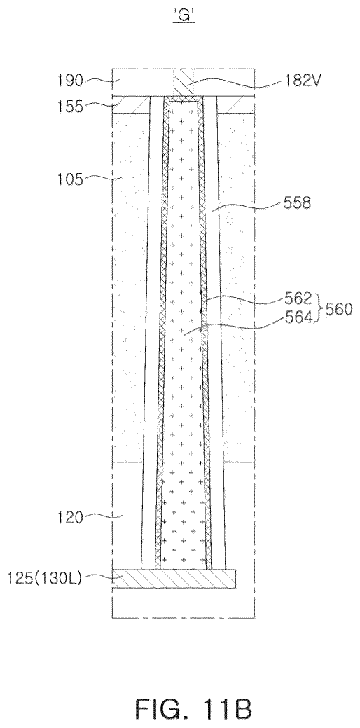

FIGS. 11A and 11B are diagrams illustrating a semiconductor device according to one or more example embodiments. FIG. 11A is a cross-sectional view illustrating elements modified in the cross-sectional structure of FIG. 4A according to one or more example embodiments. FIG. 11B is a partially enlarged view of a region indicated by “G” of FIG. 1A according to one or more example embodiments.

Referring to FIGS. 11A and 11B, the first through-via 160 described above may be replaced with a first through-via 560 having side surfaces inclined such that a width thereof increases in a direction oriented from top to bottom. As described above, the second through-via 170 may have a side surface inclined such that a width thereof decreases in a direction oriented from top to bottom. Accordingly, one of the first through-via 560 and the second through-via 170 may have a positive inclination, and the other thereof may have a negative inclination. A side surface of the first through-via 560 may have a different inclination from a side surface of the second through-via 170.

The first through-via 560 may include a conductive pillar 464 and a barrier layer 562 covering or at least partially covering a side surface and an upper surface of the conductive pillar 464. The first insulating spacer 158 described above may be replaced with a first insulating spacer 558 covering or at least partially covering a side surface of the first through-via 560.

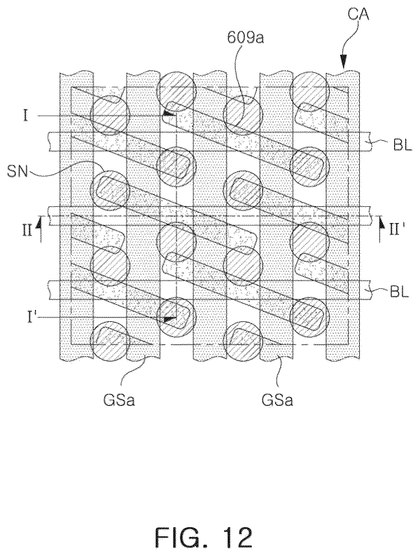

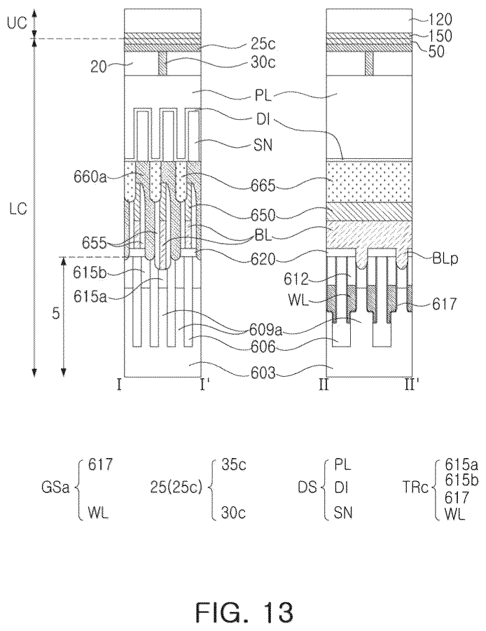

FIGS. 12 and 13 are diagrams illustrating an example of a memory structure of a semiconductor device according to one or more example embodiments. Referring to FIGS. 12 and 13, an example of the lower chip structure LC including the memory structure MS (see FIG. 4A) described above will be described. FIG. 12 is a plan view illustrating an example of the memory structure MS (see FIG. 4A) described above according to one or more example embodiments. FIG. 13 is a cross-sectional view schematically illustrating regions taken along lines I-I′ and II-II′ of FIG. 12 according to one or more example embodiments.

Referring to FIGS. 12 and 13, the lower base 5 of the lower structure LC may include a substrate 603, cell active regions 609a on the substrate 603, and a cell device isolation region 606 disposed on the substrate 603 and disposed on a side surface of the cell active regions 609a. The cell active regions 609a may protrude from the substrate 603 in a vertical direction. The cell device isolation region 606 may be formed by shallow trench isolation. The cell device isolation region 606 may be formed of an insulating material such as silicon oxide and/or silicon nitride. The cell device isolation region cSTI of FIG. 4A may be formed simultaneously with the cell device isolation region 606.

The lower structure LC may include cell gate structures GSa embedded in the cell active regions 609a and extending into the cell device isolation region 606, and cell gate capping layers 612 on the cell gate structures GSa. The cell gate capping layers 617 may be formed of an insulating material.

The cell gate structures GSa and the cell gate capping layers 612 may be disposed in cell gate trenches crossing the cell active region 609a and extending into the cell device isolation region 606.

Each of the gate structures GSa may include a cell gate capping layer 617 and a cell gate electrode WL on the cell gate capping layer 617. The cell gate electrodes WL may be word lines.

The lower structure LC may further include first source/drain regions 615a and second source/drain regions 615b disposed in the cell active regions 609a. The cell gate structures GS and the first and second source/drain regions 615a and 615b may constitute cell transistors TRc. The cell transistors TRc may be cell switching devices.

The lower structure LC includes a buffer insulating layer 620 on the cell active regions 609a and the cell device isolation region 606, bit lines BL disposed on the buffer insulating layer 620 and including plug portions BLP penetrating through the buffer insulating layer 620, bit line capping layers 650 on the bit lines BL, cell contact structures 660a disposed on both sides of the bit lines BL and including pad portions extending onto the bit line capping layers 650, an insulating isolation structure 665 disposed between the pad portions of the cell contact structures 660a and extending downward, and insulating spacers 655 on the side surfaces of the bit line capping layers 650 and the bit lines BL.

The plug portions BLP of the bit lines BL may be electrically connected to the first source/drain regions 615a. The cell contact structures 660a may be electrically connected to the second source/drain regions 615b.

The data storage structure DS described in FIG. 4A may be disposed on the cell contact structures 660a and the insulating isolation structure 665. In the data storage structure DS, the first electrodes SN may be electrically connected to the cell contact structures 660a, the dielectric layer DI may cover or at least partially cover the first electrodes SN, and the second electrode PL may be disposed on the dielectric layer DI.

As described in FIG. 4A, the lower insulating structure 20 may cover or at least partially cover the data storage structure DS, the vertical portion 30c of the third sub-routing lower wiring structure 25c may contact the second electrode PL, and an upper surface of the horizontal portion 35c of the third sub-routing lower wiring structure 25c may be contact the lower bonding insulating layer 50.

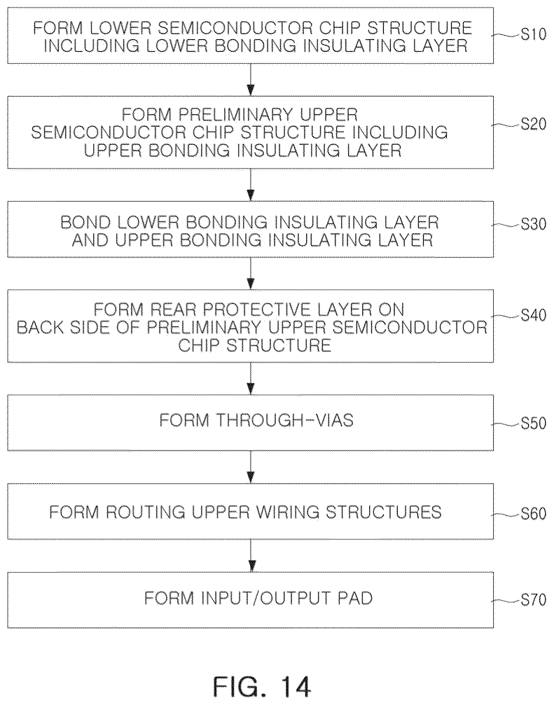

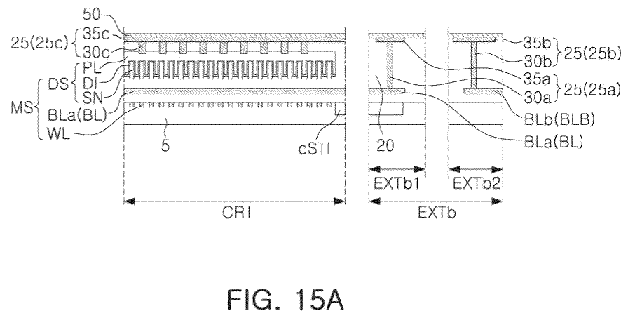

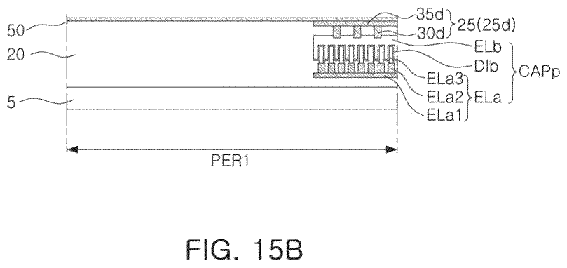

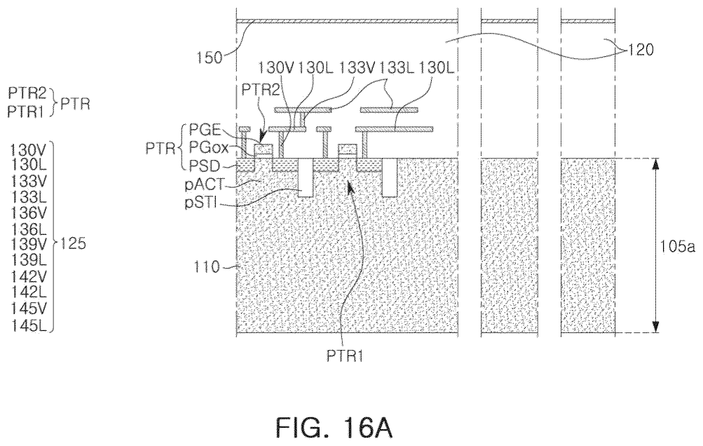

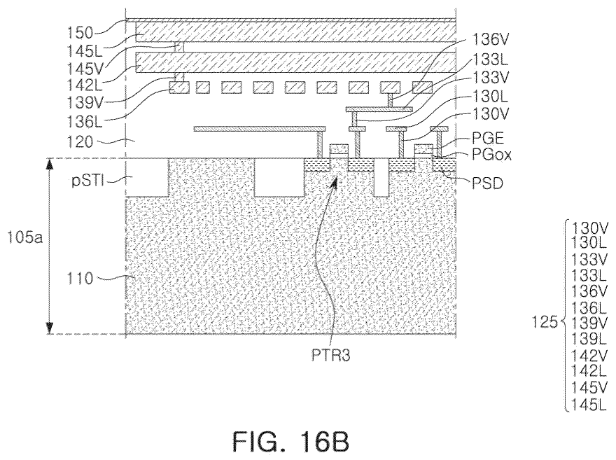

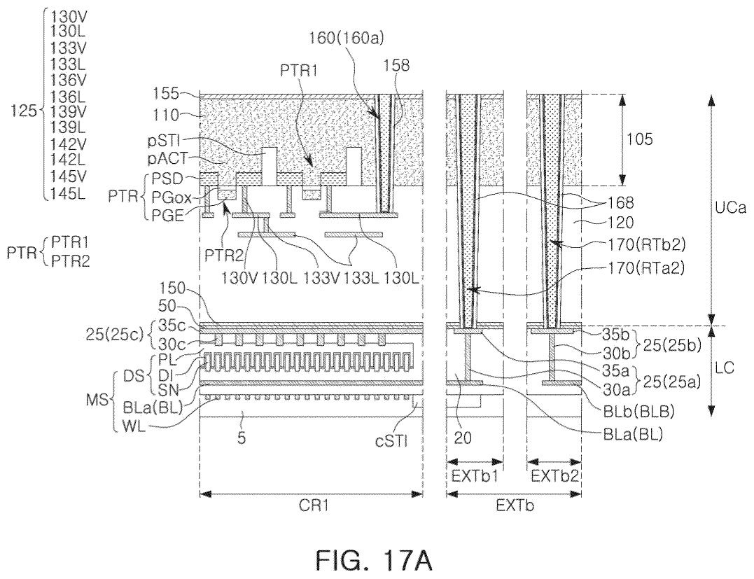

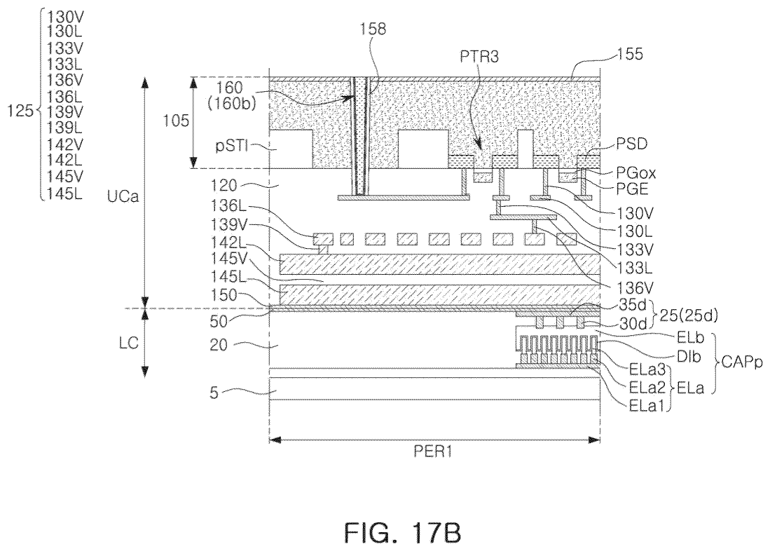

Next, referring to FIGS. 14 to 17B, an example of a method of forming a semiconductor device according to example embodiments of the present disclosure will be described. In FIGS. 14 to 17B, FIG. 14 is a flowchart illustrating an example of a method of manufacturing a semiconductor device according to one or more example embodiments. FIGS. 15A and 15B are cross-sectional views illustrating an example of a method of forming a lower chip structure according to one or more example embodiments. FIGS. 16A and 16B are cross-sectional views illustrating an example of a method of forming a preliminary upper chip structure according to one or more example embodiments. FIGS. 17A and 17B are cross-sectional views illustrating bonding of a lower chip structure and a preliminary upper chip structure according to one or more example embodiments. FIGS. 15A, 16A, and 17A are cross-sectional views corresponding to a cross-sectional structure of FIG. 4A, and FIGS. 15B, 16B, and 17B are cross-sectional views corresponding to a cross-sectional structure of FIG. 4B.

Referring to FIGS. 14, 15A, and 15B, in operation S10, a lower semiconductor chip structure including a lower bonding insulating layer 50 may be formed. The lower semiconductor chip structure may be the lower semiconductor chip structure LC (see FIGS. 4A and 4B) as illustrated in FIGS. 4A and 4B. Accordingly, as illustrated in FIG. 4A, the lower semiconductor chip structure may include the lower base 5, the memory structures MS, the power capacitor CAPp, the lower insulating structure 20, the routing lower wiring structures 25, and the lower bonding insulating layer 50.

Referring to FIGS. 14, 16A, and 16B, in operation S20, a preliminary upper semiconductor chip structure including an upper bonding insulating layer 150 may be formed.

Forming the preliminary upper semiconductor chip structure may include forming a preliminary upper base 105a, forming peripheral transistors PTR on the preliminary upper base 105a, forming a routing intermediate wiring structure 125 and an intermediate insulating structure 120 covering or at least partially covering the routing intermediate wiring structure 125 on the preliminary upper base 105a, and forming the upper bonding insulating layer 150 on the routing intermediate wiring structure 125 and the intermediate insulating structure 120.

The formation of the preliminary upper base 105a may include forming a peripheral device isolation region pSTI for limiting peripheral active regions pACT on the upper semiconductor substrate 110. As described in FIGS. 4A and 4B, the routing intermediate wiring structure 125 may include vertical portions 130V, 133V, 136V, 139V, 142V and 145V and horizontal portions 130L, 133L, 136L, 139L, 142L and 145L.

Referring to FIGS. 14, 16A, and 16B, in operation S30, the lower bonding insulating layer 50 and the upper bonding insulating layer 150 may be bonded to each other. Accordingly, the lower bonding insulating layer 50 of the lower chip structure LC in FIGS. 14A and 14B may be bonded to the upper bonding insulating layer 150 of the preliminary upper chip structure in FIGS. 15A and 15B, thereby bonding the lower chip structure LC and the preliminary upper chip structure.

In operation S40, a rear protective layer 155 may be formed on a back side of the preliminary upper semiconductor chip structure. Accordingly, a preliminary upper chip structure UCa formed up to the rear protective layer 155 may be formed on the lower chip structure LC.

The rear protective layer 155 may include at least one insulating material layer. The preliminary upper base 105a (see FIGS. 16A and 16B) may include the rear protective layer 155 and may be formed of an upper base 105.

In operation S50, through-vias 160 and 170 may be formed. The through-vias 160 and 170 may include first through-vias 160 and second through-vias 170.

The first through-vias 160 may penetrate through the upper base 105 to extend downward and may be connected to the routing intermediate wiring structure 125.

The second through-vias 170 may penetrate through the upper base 105 to extend downward and penetrate the intermediate insulating structure 120, the upper bonding insulating layer 150, and the lower bonding insulating layer 50, and may be connected to the routing lower wiring structures 25.

In one example, the first through-vias 160 and the second through-vias 170 may be formed simultaneously.

In another example, after forming the first through-vias 160, the second through-vias 170 may be formed.

In another example, after forming the second through-vias 170, the first through-vias 160 may be formed.

Referring again to FIGS. 4A to 4D, in operation S60, routing upper wiring structures 180a and 180b may be formed. The routing upper wiring structures 180a and 180b may be formed on the preliminary upper chip structure UCa (see FIGS. 17A and 17B). The routing upper wiring structures 180a and 180b may be embedded in the upper insulating structure 190 formed on the preliminary upper chip structure UCa (see FIGS. 17A and 17B).

In operation S70, an input/output pad 196 may be formed. A capping insulating layer 193 may be formed on the upper insulating structure 190. The capping insulating layer 193 may have an opening exposing an upper surface of the input/output pad 196.

According to example embodiments, the semiconductor device may be provided which may include a lower semiconductor chip including a memory structure, and an upper semiconductor chip including a peripheral circuit, thereby increasing the degree of integration of the semiconductor device.

Furthermore, an optimal routing structure may be provided which electrically connects the lower semiconductor chip and the upper semiconductor chip, to provide the semiconductor device with improved electrical characteristics.

The various and beneficial advantages and effects of example embodiments are not limited to the above description, and will be more easily understood in the course of describing specific example embodiments.

Each of the embodiments provided in the above description is not excluded from being associated with one or more features of another example or another embodiment also provided herein or not provided herein but consistent with the disclosure

While the disclosure has been particularly shown and described with reference to embodiments thereof, it will be understood that various changes in form and details may be made therein without departing from the spirit and scope of the following claims.

What is claimed is:

1. A semiconductor device comprising:
a lower chip structure comprising a memory structure and a lower wiring structure connected to the memory structure; and
an upper chip structure on the lower chip structure,
wherein the upper chip structure comprises:
an upper base;
peripheral transistors below the upper base;
an intermediate wiring structure below the upper base and connected to the peripheral transistors;
an upper wiring structure on the upper base;
a first through-via penetrating the upper base between the upper wiring structure and the intermediate wiring structure, the first through-via connecting the upper wiring structure and the intermediate wiring structure; and
a second through-via extending respectively downward and penetrating the upper base between the upper wiring structure and the lower wiring structure, the second through-via connecting the upper wiring structure and the lower wiring structure.

2. The semiconductor device of claim 1, wherein the lower chip structure further comprises a lower bonding insulating layer on the memory structure and the lower wiring structure, and
wherein the upper chip structure further comprises an upper bonding insulating layer bonded to the lower bonding insulating layer and below the upper base, the peripheral transistors and the intermediate wiring structure.

3. The semiconductor device of claim 2, wherein the second through-via comprises a portion penetrating the upper base,
wherein the second through-via continuously extends respectively downward from the portion penetrating the upper base, and
wherein the second through-via penetrates the upper bonding insulating layer and the lower bonding insulating layer.

4. The semiconductor device of claim 1, wherein the peripheral transistors vertically overlap the memory structure.

5. The semiconductor device of claim 1, wherein an upper surface of the first through-via is at a level that is substantially the same as a level of an upper surface of the second through-via, and
wherein a lower surface of the first through-via is at a level that is higher than a level of a lower surface of the second through-via.

6. The semiconductor device of claim 1, wherein a maximum width of the second through-via is greater than a maximum width of the first through-via.

7. The semiconductor device of claim 1, wherein the first through-via comprises a first conductive pillar and a first barrier layer,
wherein the second through-via comprises a second conductive pillar and a second barrier layer, and
wherein the second barrier layer at least partially covers a side surface of the second conductive pillar and a lower surface of the second conductive pillar.

8. The semiconductor device of claim 7, wherein the first barrier layer at least partially covers a side surface of the first conductive pillar and a lower surface of the first conductive pillar, and
wherein the first barrier layer contacts the lower wiring structure.

9. The semiconductor device of claim 7, wherein the first barrier layer at least partially covers a side surface of the first conductive pillar and an upper surface of the first conductive pillar, and
wherein the first barrier layer contacts the upper wiring structure.

10. The semiconductor device of claim 1, further comprising:
a first insulating spacer on a side surface of the first through-via; and
a second insulating spacer on the side surface of the second through-via,
wherein the first through-via is spaced apart from the upper base by the first insulating spacer, and
wherein the second through-via is spaced apart from the upper base by the second insulating spacer.

11. The semiconductor device of claim 1, wherein the memory structure comprises:
cell switching devices, wherein each of the cell switching devices comprises a first cell source/drain region, a second cell source/drain region, and a cell gate electrode;
bit lines respectively connected to the first cell source/drain regions of the cell switching devices; and
a data storage structure connected to the second cell source/drain regions of the cell switching devices, and
wherein the data storage structure comprises:
first electrodes respectively connected to the second cell source/drain regions of the cell switching devices;
a second electrode configured to at least partially cover the first electrodes; and
a dielectric layer between the first electrodes and the second electrode.

12. A semiconductor device comprising:
a lower chip structure comprising a first memory region, a second memory region, and an extension region between the first memory region and the second memory region; and
an upper chip structure on the lower chip structure,
wherein the lower chip structure further comprises:
a first bit line in the first memory region and extending into the extension region;
a second bit line in the second memory region and extending into the extension region; and
routing lower wiring structures electrically connected to the first bit line and the second bit line,
wherein the upper chip structure includes:
an upper base;
peripheral transistors vertically overlapping the first memory region and below the upper base;
routing intermediate wiring structures below the upper base and connected to the peripheral transistors;
routing upper wiring structures on the upper base;
first through-vias penetrating the upper base and connecting the routing upper wiring structures and the routing intermediate wiring structures; and
second through-vias penetrating the upper base and connecting the routing upper wiring structures and the routing lower wiring structures,
wherein the second through-vias are on the extension region, and
wherein the first through-vias are on the first memory region.

13. The semiconductor device of claim 12, wherein the lower chip structure further comprises a lower bonding insulating layer,
wherein the upper chip structure further comprises an upper bonding insulating layer bonded to the lower bonding insulating layer,
wherein the peripheral transistors and the routing intermediate wiring structures constitute a sense amplifier, and
wherein the sense amplifier is between the upper base and the upper bonding insulating layer.

14. The semiconductor device of claim 13, wherein the second through-vias continuously extend respectively downward in the upper base and penetrate the upper bonding insulating layer and the lower bonding insulating layer.

15. The semiconductor device of claim 12, wherein the routing lower wiring structures comprise:
a first sub-routing lower wiring structure connected to the first bit line; and
a second sub-routing lower wiring structure connected to the second bit line,
wherein the first through-vias comprise a first sub-routing through-via and a second sub-routing through-via,
wherein the second through-vias comprise:
a third sub-routing through-via connected to the first sub-routing lower wiring structure; and
a fourth sub-routing through-via connected to the second sub-routing lower wiring structure, and
wherein the routing upper wiring structures comprise:
a first sub-routing upper wiring structure connecting the first sub-routing through-via and the third sub-routing through-via; and
a second sub-routing upper wiring structure connecting the second sub-routing through-via and the fourth sub-routing through-via.

16. The semiconductor device of claim 15, wherein the peripheral transistors and the routing intermediate wiring structures constitute a sense amplifier,
wherein the lower chip structure further comprises a data storage structure,
wherein the first bit line is configured to sense data stored in the data storage structure, and
wherein the second bit line comprises a complementary bit line.

17. The semiconductor device of claim 12, wherein the upper base comprises:
an upper semiconductor substrate;
peripheral active regions below the upper semiconductor substrate; and
a peripheral device isolation region below the upper semiconductor substrate and defining side surfaces of the peripheral active regions.

18. A semiconductor device comprising:
a lower chip structure comprising a memory structure and a lower wiring structure connected to the memory structure; and
an upper chip structure on the lower chip structure,
wherein the upper chip structure comprises:
an upper base;
peripheral transistors below the upper base;
an intermediate wiring structure below the upper base and connected to the peripheral transistors;
an upper wiring structure on the upper base; and
through-vias penetrating at least the upper base,
wherein the intermediate wiring structure comprises intermediate vias at respective different levels and intermediate wirings at respective different levels,
wherein the upper wiring structure comprises at least one upper via and at least one upper wiring, and
wherein a number of the intermediate wirings is greater than a number of the at least one upper wiring.

19. The semiconductor device of claim 18, wherein the through-vias comprises:
a first through-via penetrating the upper base between the upper wiring structure and the intermediate wiring structure, the first through-via connecting the upper wiring structure and the intermediate wiring structure; and
a second through-via extending respectively downward and penetrating the upper base between the upper wiring structure and the lower wiring structure, the second through-via connecting the upper wiring structure and the lower wiring structure, and
wherein a maximum width of the second through-via is greater than a maximum width of the first through-via.

20. The semiconductor device of claim 19, wherein the lower chip structure further comprises a lower bonding insulating layer on the memory structure and the lower wiring structure,
wherein the upper chip structure further comprises an upper bonding insulating layer bonded to the lower bonding insulating layer and below the upper base, the peripheral transistors and the intermediate wiring structure,
wherein the first through-via is at a level that is higher than a level of the upper bonding insulating layer,
wherein the first through-via vertically overlaps the memory structure,
wherein the second through-via comprises a portion penetrating the upper base,
wherein the second through-via continuously extends respectively downward from the portion penetrating the upper base, and
wherein the second through-via penetrates the upper bonding insulating layer and the lower bonding insulating layer.
